(19) United States
(12) Patent Application Publication
(10) Pub. No.: US 2021/0184176 A1
(43) Pub. Date: Jun. 17, 2021

(54) DISPLAY PANEL AND DISPLAY DEVICE

(71) Applicant: Shenzhen China Star Optoelectronics Semiconductor Display Technology Co., Ltd., Shenzhen, Guangdong (CN)

(72) Inventors: Aiguo TU, Shenzhen, Guangdong (CN); Jinchuan LI, Shenzhen, Guangdong (CN); Feng WEI, Shenzhen, Guangdong (CN); Yuanchun WU, Shenzhen, Guangdong (CN)

(21) Appl. No.: 16/759,342

(22) PCT Filed: Dec. 27, 2019
(86) PCT No.: PCT/CN2019/128953

§ 371 Date: Apr. 26, 2020

(30) Foreign Application Priority Data
Dec. 17, 2019 (CN) 201911303475.7

(51) Int. Cl. H01L 51/52; H01L 27/32

(52) U.S. Cl. CPC H01L 51/5271; H01L 27/322; H01L 51/5218; H01L 2251/5315; H01L 51/5284; H01L 27/3246

(57) ABSTRACT

The present application provides a display panel and a display device. The display panel includes multiple pixel units. The display panel includes: a metal reflective layer surrounding the pixel units; first electrodes arranged corresponding to the pixel units, respectively; and a pixel defining layer covering the first electrodes and the metal reflective layer. The pixel defining layer has openings, and each of the first electrodes is partially exposed from the corresponding opening.

### FIELD OF DISCLOSURE

The present application relates to a field of display panel technology and in particular, to a display panel and a display device.

### DESCRIPTION OF RELATED ART

For large-sized organic light-emitting diode (OLED) display devices, in order to achieve 8K resolution, a bottom-gate device has a lower aperture ratio due to an increase in the number of thin film transistors (TFTs), and a lifespan of the OLED device is reduced to one third of a lifespan of a 4K OLED TV. Top-gate devices mainly include two technical solutions: one is top-emission white light plus a color filter, and the other one is top-emission blue light plus a quantum dot color filter (or a quantum dot film).

The large-sized OLED display devices, especially quantum dot organic electroluminescent devices with blue light and quantum dot color filters, have low conversion efficiency of quantum dots, so there is an urgent need to improve the efficiency of a light conversion layer.

Therefore, it is necessary to develop a new type of display panel to overcome the above problem.

### SUMMARY

It is an objective of the present invention to provide a display panel which can solves a problem of low conversion efficiency of quantum dots in a conventional display panel.

Accordingly, the present invention provides a display panel which comprises a plurality of pixel units. The display panel comprises: a metal reflective layer surrounding the pixel units; a plurality of first electrodes disposed corresponding to the pixel units, respectively; and a pixel defining layer covering the first electrodes and the metal reflective layer, wherein openings are defined in the pixel defining layer, and each of the first electrodes is partially exposed from the corresponding opening.

According to one embodiment of the present invention, the display panel further comprises a plurality of light emitting layers, wherein the light emitting layers are disposed in the openings of the pixel defining layer and are blue light emitting layers.

According to one embodiment of the present invention, the display panel further comprises a light conversion layer disposed on the light emitting layers, wherein the light conversion layer is provided with a plurality of quantum dot light conversion layers, each of the quantum dot light conversion layers is disposed corresponding to one of the light emitting layers, and the quantum dot light conversion layers comprise a red quantum dot light conversion layer and a green quantum dot light conversion layer.

According to one embodiment of the present invention, the display panel further comprises a protruding photoresist layer surrounding the pixel units, wherein the metal reflective layer covers a surface of the protruding photoresist layer.

The protruding photoresist layer and the metal reflective layer are formed around the pixel units. The metal reflective layer reduces light leakage of adjacent pixels at a large viewing angle and also improves a blue light utilization rate of a quantum dot organic electroluminescent device.

According to one embodiment of the present invention, the first electrodes are reflective anodes.

According to one embodiment of the present invention, the display panel further comprises an array substrate disposed under the pixel defining layer, the array substrate comprising: a base substrate; a thin film transistor structure layer disposed on the base substrate; a planarization layer disposed on the thin film transistor structure layer; and a pixel electrode layer disposed on the planarization layer and connected to the thin film transistor structure layer through a via hole of the planarization layer.

According to one embodiment of the present invention, a transparent oxide film is disposed on the metal reflective layer.

According to one embodiment of the present invention, a transparent oxide film is disposed under the metal reflective layer.

According to one embodiment of the present invention, the display panel further comprises a black photoresist layer, wherein the black photoresist layer is disposed on the pixel defining layer and is disposed in a same layer as the light conversion layer.

According to one embodiment of the present invention, the display panel further comprises an encapsulation cover plate disposed above the light conversion layer.

The present invention further provides a display device. The display device comprises the display panel mentioned above.

### ADVANTAGES OF THE PRESENT INVENTION

Compared with conventional techniques, the present invention provides a display panel and a display device. A protruding photoresist layer and a metal reflective layer are formed around pixel units. The metal reflective layer reduces light leakage of adjacent pixels at a large viewing angle and also improves a blue light utilization rate of a quantum dot organic electroluminescent device.

### BRIEF DESCRIPTION OF DRAWINGS

The following detailed description of the present application will make the technical solutions and the advantages of the present application obvious in conjunction with the accompanying drawings and specific embodiments.

FIG. 1 is a schematic structural view illustrating a display panel according a first embodiment of the present invention; and

FIG. 2 is a schematic structural view illustrating the display panel according to a second embodiment of the present invention.

### DETAILED DESCRIPTION OF EMBODIMENTS

The technical solutions of the present application will be clearly and completely described below with reference to the accompanying drawings and embodiments of the present application. Obviously, the described embodiments are only some embodiments of the present application, but not all the embodiments. Based on the embodiments in the present application, all other embodiments obtained by those skilled in the art without creative work fall into the protection scope of the present application.

In the description of this application, it should be understood that directional terms, such as “center”, “longitudinal”, “transverse”, “length”, “width”, “thickness”, “upper”, “lower”, “front”, “rear”, “left”, “right”, “vertical”, “horizontal”, “top”, “bottom”, “inside”, “outside”, “clockwise”, and “counterclockwise”, are illustrative based on the orientation or positional relationship shown in the drawings. The directional terms are only for ease of the description, rather than indicating or implying that the device or element referred to must have a specific orientation, or structured and operated in a specific orientation, Therefore, these directional terms cannot be understood as limitations on the present application. In addition, the terms “first” and “second” are used for illustrative purposes only, and cannot be understood as indicating or implying relative importance or implicitly indicating the number of technical features. Therefore, the features defined as “first” and “second” may explicitly or implicitly include one or more of the features. In the description of the present application, “multiple” means two or more, unless specifically defined otherwise.

In the description of the present application, it should be noted that the terms “installation”, “connected”, and “coupled” should be understood in a broad sense unless explicitly specified and limited otherwise. To be specific, elements may be, for example, fixedly connected, removably connected, or connected in an integral form; and elements can be, for example, mechanically connected, electrically connected, or in communication with each other. The elements can be directly connected or can be indirectly connected through an intermediate medium; or alternatively, there is internal communication or an interactive relationship between two elements. For those of ordinary skill in the art, specific meanings of the above terms in the present application can be understood on a case-by-case basis.

In the present application, unless explicitly specified and defined otherwise, the first element being “on” or “under” the second element can mean that the first element is in direct contact with the second element, and can also mean that the first element is directly above and obliquely over the second element, or just mean that the first element is at a higher level than the second element. The first element being “below”, “under”, or “beneath” the second element means that the first element is directly below and obliquely below the second element, or merely indicates that the first element is at a lower level than the second element.

Different embodiments or examples are provided below for implementing different structures of the present application. For ease of illustration of the present disclosure, the components and configurations of specific examples are described below. Certainly, they are merely examples and are not intended to limit the present application. In addition, reference numbers and/or reference letters can be repeated in different examples of the present application, and such repetition is for the purpose of simplicity and clarity and does not indicate the relationship between the various embodiments and/or configurations discussed. In addition, although examples of various specific processes and materials are provided in the present application, those of ordinary skill in the art may be aware of the use of other processes and/or other materials.

### First Embodiment

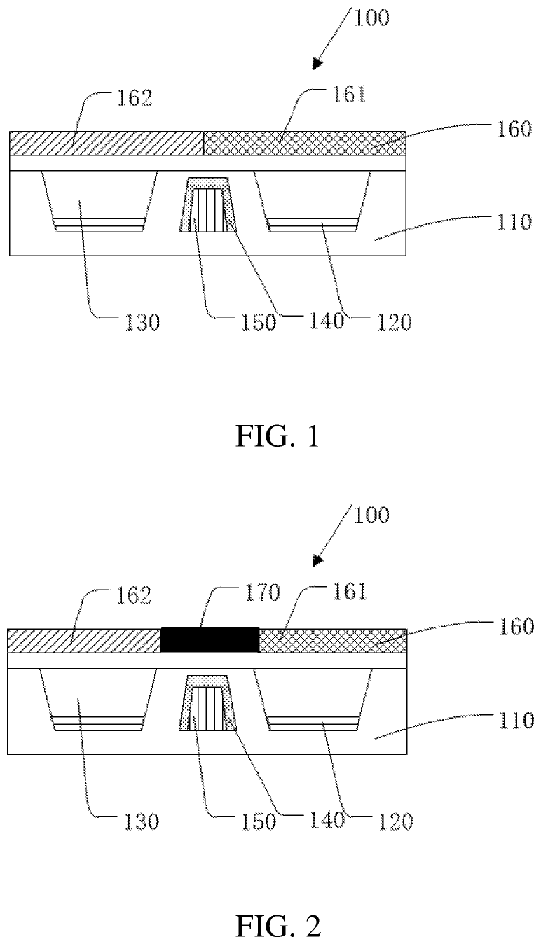

Referring to FIG. 1, a display panel 100 is provided according to the present embodiment. The display panel 100 comprises a plurality of pixel units. The display panel comprises a pixel defining layer 110, a metal reflective layer 140, a plurality of reflective anodes 120 (first electrodes), a plurality of light emitting layers 130, a metal reflective layer 140, a protruding photoresist layer 150, and a light conversion layer 160.

The protruding photoresist layer 150 surrounds the pixel units. The metal reflective layer 140 covers a surface of the protruding photoresist layer 150.

The protruding photoresist layer 150 and the metal reflective layer 140 are formed around the pixel units. The metal reflective layer 140 reduces light leakage of adjacent pixels at a large viewing angle and also improves a blue light utilization rate of a quantum dot organic electroluminescent device.

The pixel defining layer 110 covers the first electrodes and the metal reflective layer 140. Openings are defined in the pixel defining layer 110. Each of the reflective anodes 120 is partially exposed from the corresponding opening. The reflective anodes 120 are disposed corresponding to the pixel units, respectively.

The display panel 100 further comprises the light emitting layers 130, wherein the light emitting layers 130 are disposed in the openings of the pixel defining layer 110 and are blue light emitting layers 130.

The light conversion layer 160 is disposed on the light emitting layers 130. The light conversion layer 160 is provided with a plurality of quantum dot light conversion layers, each of the quantum dot light conversion layers is disposed corresponding to one of the light emitting layers 130, and the quantum dot light conversion layers 160 comprise a red quantum dot light conversion layer 161 and a green quantum dot light conversion layer 162.

The display panel 100 further comprises an array substrate disposed under the pixel defining layer 110. The array substrate comprising: a base substrate; a thin film transistor structure layer disposed on the base substrate; a planarization layer disposed on the thin film transistor structure layer; and a pixel electrode layer disposed on the planarization layer and connected to the thin film transistor structure layer through a via hole of the planarization layer. The present embodiment focuses on the metal reflective layer 140, so the array substrate is not described in detail here.

In alternative embodiments, a transparent oxide film is disposed on the metal reflective layer 140. In other embodiments, a transparent oxide film is disposed under the metal reflective layer 140.

The display panel 100 further comprises an encapsulation cover plate, which is disposed above the light conversion layer 160.

The present application further provides a display device. The display device comprises the display panel 100 of the present embodiment.

The advantages of the present embodiment: The present invention provides the display panel 100 and the display device. The protruding photoresist layer 150 and the metal reflective layer 140 are formed around the pixel units. The metal reflective layer 140 reduces light leakage of adjacent pixels at a large viewing angle and also improves a blue light utilization rate of a quantum dot organic electroluminescent device.

### Second Embodiment

The display panel of the present embodiment defines the light conversion layer 160. A structure of the second embodiment is similar to the structure of the first embodiment. For the same parts in the structure, their descriptions can be found in the first embodiment and are not repeated here. Please refer to FIG. 2. FIG. 2 is a schematic structural view of the display panel 100 of the present embodiment. The main difference between the two embodiments is that the display panel of the second embodiment further includes a black photoresist layer 170 provided on the pixel defining layer 110. The black photoresist layer 170 is provided in the same layer as the light conversion layer 160. The black photoresist layer 170 can prevent light leakage from adjacent pixels and improve the color gamut of the display panel.

The present embodiment further provides a display device. The display device comprises the display panel 100 of the second embodiment.

Advantages of the present invention: The present invention provides the display panel 100 and the display device. The protruding photoresist layer 150 and the metal reflective layer 140 are formed around the pixel units. The metal reflective layer 140 reduces light leakage of adjacent pixels at a large viewing angle and also improves a blue light utilization rate of a quantum dot organic electroluminescent device.

In the above embodiments, the description of each embodiment has its own emphasis. For those which are not described in detail in one embodiment, related descriptions can be found in other embodiments.

The display panel of the present application has been described in detail above. The working principles and embodiments of the present application are explained above. The description of the above embodiments is only for ease of understanding the technical solution of the present application and its core ideas. Those of ordinary skill in the art should understand that, modifications can be made to the technical solutions described in the foregoing embodiments, or equivalent replacements can be made for some of the technical features. These modifications or replacements should still fall within the protection scope of the present application.

What is claimed is:

1. A display panel comprising a plurality of pixel units, the display panel comprising:
a metal reflective layer surrounding the pixel units;
a plurality of first electrodes disposed corresponding to the pixel units, respectively; and
a pixel defining layer covering the first electrodes and the metal reflective layer, wherein openings are defined in the pixel defining layer, and each of the first electrodes is partially exposed from the corresponding opening.

2. The display panel according to claim 1, further comprising a plurality of light emitting layers, wherein the light emitting layers are disposed in the openings of the pixel defining layer and are blue light emitting layers.

3. The display panel according to claim 2, further comprising a light conversion layer disposed on the light emitting layers, wherein the light conversion layer is provided with a plurality of quantum dot light conversion layers, each of the quantum dot light conversion layers is disposed corresponding to one of the light emitting layers, and the quantum dot light conversion layers comprise a red quantum dot light conversion layer and a green quantum dot light conversion layer.

4. The display panel according to claim 1, further comprising a protruding photoresist layer surrounding the pixel units, wherein the metal reflective layer covers a surface of the protruding photoresist layer.

5. The display panel according to claim 1, wherein the first electrodes are reflective anodes.

6. The display panel according to claim 1, further comprising an array substrate disposed under the pixel defining layer, the array substrate comprising:
a base substrate;
a thin film transistor structure layer disposed on the base substrate;
a planarization layer disposed on the thin film transistor structure layer; and
a pixel electrode layer disposed on the planarization layer and connected to the thin film transistor structure layer through a via hole of the planarization layer.

7. The display panel according to claim 1, further comprising a transparent oxide film disposed on the metal reflective layer.

8. The display panel according to claim 1, further comprising a transparent oxide film disposed under the metal reflective layer.

9. The display panel according to claim 1, further comprising a black photoresist layer, wherein the black photoresist layer is disposed on the pixel defining layer and is disposed in a same layer as the light conversion layer.

10. A display device comprising the display panel of claim 1.

11. The display device according to claim 10, further comprising a plurality of light emitting layers, wherein the light emitting layers are disposed in the openings of the pixel defining layer and are blue light emitting layers.

12. The display device according to claim 11, further comprising a light conversion layer disposed on the light emitting layers, the light conversion layer is provided with a plurality of quantum dot light conversion layers, each of the quantum dot light conversion layers is disposed corresponding to one of the light emitting layers, and the quantum dot light conversion layers comprise a red quantum dot light conversion layer and a green quantum dot light conversion layer.

13. The display panel according to claim 10, further comprising a protruding photoresist layer surrounding the pixel units, wherein the metal reflective layer covers a surface of the protruding photoresist layer.

14. The display device according to claim 10, wherein the first electrode is a reflective anode.

15. The display device according to claim 10, further comprising an array substrate disposed under the pixel defining layer, the array substrate comprising:
a base substrate;
a thin film transistor structure layer disposed on the base substrate;
a planarization layer disposed on the thin film transistor structure layer; and
a pixel electrode layer disposed on the planarization layer and connected to the thin film transistor structure layer through a via hole of the planarization layer.

16. The display device according to claim 10, wherein a transparent oxide film is disposed on the metal reflective layer.

17. The display device according to claim 10, wherein a transparent oxide film is disposed under the metal reflective layer.

18. The display device according to claim 10, further comprising a black photoresist layer, wherein the black photoresist layer is disposed on the pixel defining layer and is disposed in a same layer as the light conversion layer.
